(19) United States
(12) Patent Application Publication
(10) Pub. No.: US 2014/0299177 A1
(43) Pub. Date: Oct. 9, 2014

(54) Integrated roof solar power system

(71) Applicants: Xiaolin Sha, Shanghai (CN); Yan Sha, Shanghai (CN)

(72) Inventors: Xiaolin Sha, Shanghai (CN); Yan Sha, Shanghai (CN)

(21) Appl. No.: 14/093,438

(22) Filed: Nov. 30, 2013

(30) Foreign Application Priority Data
Apr. 8, 2013 (CN) 201310119442.3
Apr. 27, 2013 (CN) 201320228684.1

(51) Int. Cl. H01L 31/048; H01L 31/18

(52) U.S. Cl. CPC H01L 31/0482; H01L 31/18
USPC 136/251; 29/428

(57) ABSTRACT

An integrated roof solar power system comprises: a roof unit, provided on a roof; a plurality of solar-cell panels, mounted on the roof unit, wherein the solar-cell panels are jointed at upper edges and lower edges in turn to form a plurality of upper and lower edge joints, and the solar-cell panels are jointed at side edges to form a plurality of side edge joints; a plurality of lower edge water-preventers, mounted on the lower edges of the solar-cell panels, to cover the upper and lower edge joints and prevent rain from infiltrating into the upper and lower edge joints; a plurality of side edge water-preventers, mounted in positions of the side edge joints, to cover the side edge joints; and a ridge element, mounted on a ridge of a building, to cover a gap between the upper edges of the solar-cell panels adjacent to the ridge.

### CROSS REFERENCE OF RELATED APPLICATION

The present invention claims priority under 35 U.S.C. 119(a-d) to CN201310119442.3, filed Apr. 8, 2013, and CN201320228684.1, filed Apr. 27, 2013.

### BACKGROUND OF THE PRESENT INVENTION

1. Field of Invention

The present invention relates to a roof solar power system, and more particularly to an integrated roof solar power system.

2. Description of Related Arts

The photovoltaic system converts the solar energy into the electric energy with solar energy battery components and auxiliary equipments. The photovoltaic system has characteristics of high reliability, long service life, no environmental pollution. The photovoltaic system can generate electricity independently, and can also be connected to the grid. The photovoltaic system has a wide developing prospect. Combining the photovoltaic system with energy saving of buildings is an advanced technology and developing direction of energy saving and emission reduction of buildings, which is valued and popularized by various parties. However, because of various reasons, there are few successful cases that photovoltaic components are actually used as new roof constructing materials by being combined closely with building roofs. In most projects of integrated building photovoltaic system, which have already been implemented, the photovoltaic components are just put on roofs of different materials, instead of being combined with roofs, and the rainproof function and the waterproof function could not be realized. Especially, the service life of the color steel roofing is only 6˜7 years. The installed photovoltaic components should be removed at first, if the color plates are required to be replaced. Thus, the construction is complicated, and the cost is high. The maintaining becomes more inconvenient in a case of leakage of rain. In another hand, the weight of the photovoltaic components and the installing fittings propose a requirement to the weight capacity of roof. In order to increase the weight capacity of roof, the cost and the difficulty of construction are certainly increased.

### SUMMARY OF THE PRESENT INVENTION

An object of the present invention is to provide an integrated roof solar power system adopting drainer and water-preventer. Conventional drilling thread connection and direct connection on metal strips are replaced by structural adhesive. The integrated roof solar power system is rainproof, and cost for waterproof facilities of roof could be saved. Thus, service life of color steel roof is extended to 20 years from 7 years, and costs of maintaining and repair of roofs in later are reduced by 50%.

Another object of the present invention is to provide an integrated roof solar power system, characterized in that the solar power system and the roof are integrated, in order to save costs for color steel roof, cement roof, etc., and provide electric to user at a same time.

A third object of the present invention is to provide an integrated roof solar power system, characterized in that waterproof structures are adopted at joints between solar-cell panels, in order to protect the roof from the rain. Thus, a disadvantage that the color steel roof has a short service life could be overcome, and costs for installing and materials of color steel, and costs for maintaining and repair in later are saved.

A fourth object of the present invention is to provide an integrated roof solar power system, wherein the solar-cell panels are installed by a ladder type method. The solar-cell panels are connected with each other to form a whole. Stability and fastness of a whole structure are increased, and the roof becomes neater and more beautiful.

A fifth object of the present invention is to provide a method for installing an integrated roof solar power system, to further construct a roof solar power station. The solar-cell panels are adhered to metal supporting stripes by structural adhesive, in such a manner that original structure of the roof will not be damaged, and weight capacity of a common building will be improved. Constructing costs of the roof are significantly saved, and construction and maintaining is easy and convenient.

Accordingly, in order to accomplish the above objects, the present invention provides an integrated roof solar power system, comprising:

a roof unit, provided on a roof;

a plurality of solar-cell panels, mounted on the roof unit, wherein each of the solar-cell panel has an upper edge, a lower edge, and two side edges, the solar-cell panels are jointed at the upper edges and the lower edges in turn to form a plurality of upper and lower edge joints, the plurality of the solar-cell panels are jointed at the side edges to form a plurality of side edge joints;

a plurality of lower edge water-preventers, mounted on the lower edges of the solar-cell panels, to cover the upper and lower edge joints and prevent rain from infiltrating into the upper and lower edge joints;

a plurality of side edge water-preventers, mounted in positions of the side edge joints, to cover the side edge joints and prevent rain from infiltrating into the side edge joints; and

a ridge element, mounted on a ridge of a building, to cover a gap between the upper edges of the solar-cell panels adjacent to the ridge and prevent rain from infiltrating into the joint.

The integrated roof solar power system provided by the present invention has a stable structure, good-looking and neat appearance. The integrated roof solar power system is rainproof. Especially, the service life of color steel roof is extended to 20 years from 7 years, and the costs of maintaining and repair of roofs in later are reduced by 50%. In another hand, fixing bases are adhered to the roof by structural adhesive, in such a manner that original structure of the roof is not damaged, and waterproof performance of the roof is further improved. Meanwhile, aluminum alloy frames of different structures are provided in the present invents. Drainer and water-preventer are provided at the joints, to lead or disperse the rain and prevent the rain from infiltrating. Shortcomings in the prior art are overcome, and the integrated roof solar power system provided by the present invention could be applied in various environment.

These and other objectives, features, and advantages of the present invention will become apparent from the following detailed description, the accompanying drawings, and the appended claims.

### BRIEF DESCRIPTION OF THE DRAWINGS

FIG. 1 is a perspective view of sectional structure of an integrated roof solar power system according to a preferred embodiment of the present invention.

FIG. 2 is a perspective view of whole structure of the integrated roof solar power system according to the preferred embodiment of the present invention.

FIG. 3 is an enlarged view of part A in FIG. 2.

FIG. 4 is a structure view of a solar-cell panel according to the preferred embodiment of the present invention.

FIG. 5 is an enlarged view of part B in FIG. 4.

FIG. 6 is a front view of a supporting fixing base according to a first preferred embodiment of the present invention.

FIG. 7 is a left view of the supporting fixing base according to the first preferred embodiment of the present invention.

FIG. 8 is a perspective view of the supporting fixing base according to the first preferred embodiment of the present invention.

FIG. 9 is a sketch view of a first adjusting plate and a base of the supporting fixing base according to the first preferred embodiment of the present invention.

FIG. 10 is a sketch view of a second adjusting plate of the supporting fixing base according to the first preferred embodiment of the present invention.

FIG. 11 is an exploded view of the first adjusting plate, the second adjusting plate, and the base, illustrating a first installing position of the first adjusting plate and the second adjusting plate, according to a second preferred embodiment of the present invention.

FIG. 12 is an exploded view of the first adjusting plate, the second adjusting plate and the base in the FIG. 11, illustrating a second installing position of the first adjusting plate and the second adjusting plate.

FIG. 13 is an exploded view of the first adjusting plate, the second adjusting plate and the base, illustrating a first installing position of the first adjusting plate and the second adjusting plate, according to a third preferred embodiment of the present invention.

FIG. 14 is an exploded view of the first adjusting plate, the second adjusting plate and the base in the FIG. 13, illustrating a second installing position of the first adjusting plate and the second adjusting plate.

FIG. 15 is a side view of the solar-cell panel according to a preferred embodiment of the present invention.

FIG. 16 is a side view of the solar-cell panel and a water channel according to a preferred embodiment of the present invention.

FIG. 17 is a connecting sketch view of the fixing supporting base, a roof, and the solar-cell panel according to a preferred embodiment of the present invention.

FIG. 18 is a perspective view of the roof having a ridge element according to a preferred embodiment of the present invention.

FIG. 19 is a partial enlarged view of the FIG. 18.

FIG. 20 is an installing sketch view of a new roof.

FIG. 21 is a whole structure view of the integrated roof solar power system according to a preferred embodiment of the present invention.

FIG. 22 is a partial enlarged view of the FIG. 21.

FIG. 23 is a partial structure view of the integrated roof solar power system according to the above preferred embodiment of the present invention.

FIG. 24 is a perspective view of a lower edge water-preventer according to the above preferred embodiment of the present invention.

FIG. 25 is a perspective view of a side edge fixer according to the above preferred embodiment of the present invention.

FIG. 26 is a structure sketch view of a side edge water-preventer according to the above preferred embodiment of the present invention.

FIG. 27 is a structure sketch view of a side eave according to the above preferred embodiment of the present invention.

FIG. 28 is a perspective view of base connecting plate according to the above preferred embodiment of the present invention.

FIG. 29 is a connecting sketch view of a lower edge base and a supporting bar according to the above preferred embodiment of the present invention.

FIG. 30 is a connecting sketch view of the solar-cell panel and the supporting bar according to the above preferred embodiment of the present invention.

FIG. 31 is a front view of the FIG. 30.

### DETAILED DESCRIPTION OF THE PREFERRED EMBODIMENT

### Embodiment 1

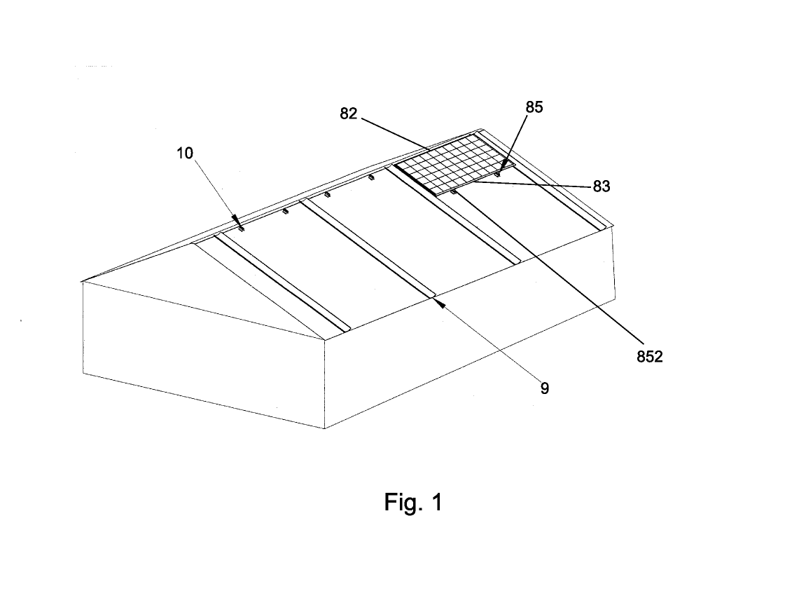

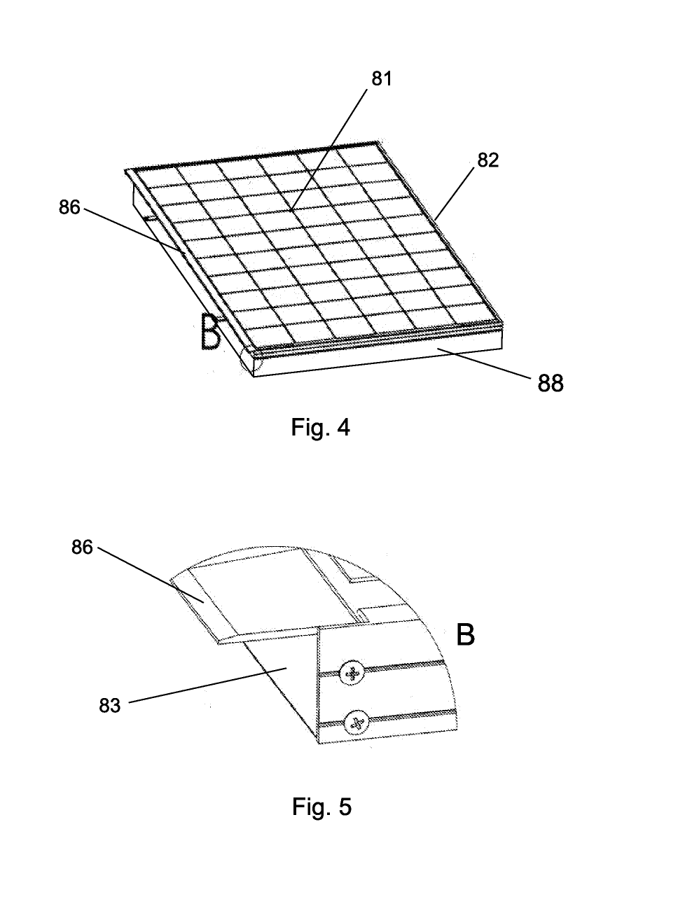

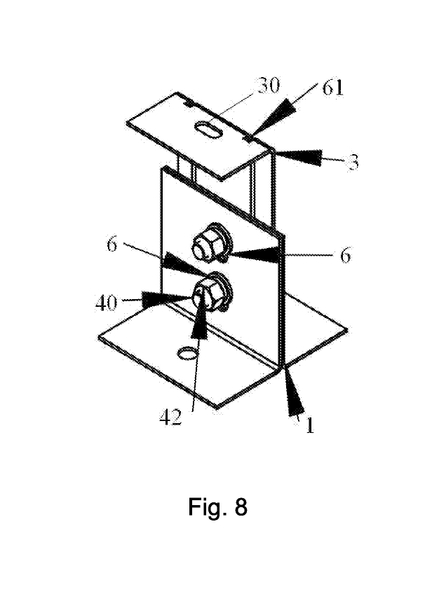

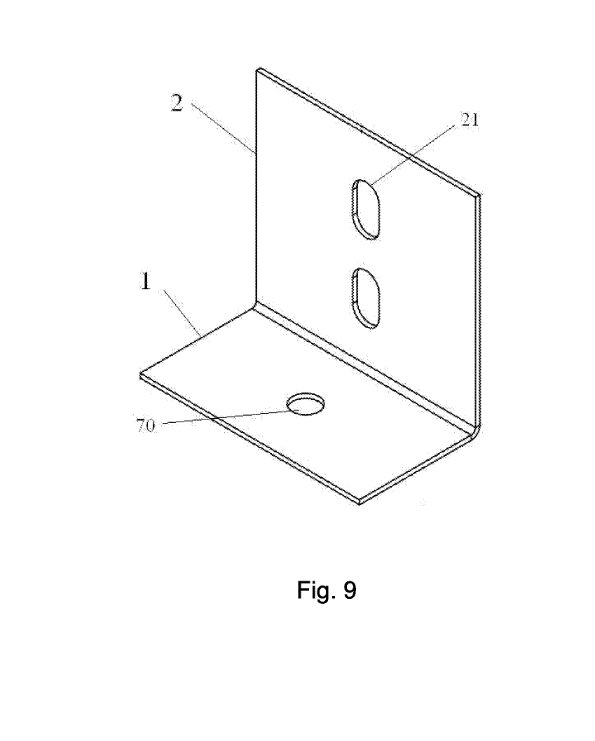

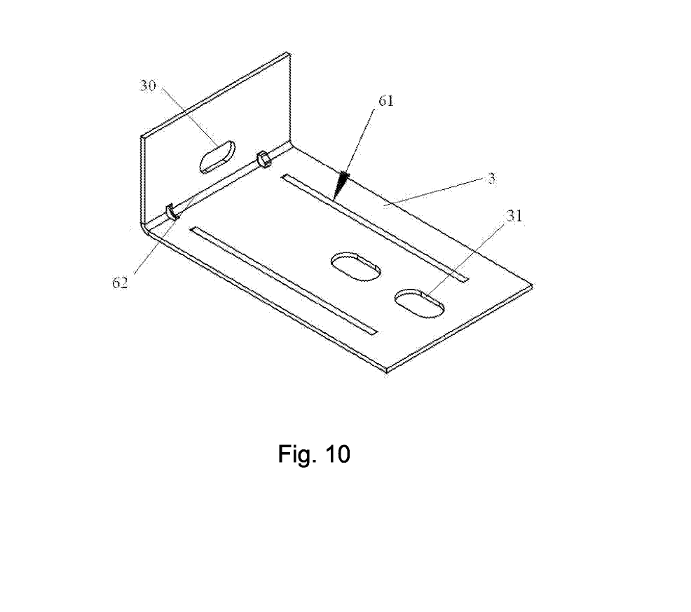

Referring to FIGS. 1-5 and FIG. 8, an integrated roof solar power system comprises:

a plurality of solar-cell panel groups 8, wherein each of the plurality of solar-cell panel group 8 comprises:
a plurality of solar-cell panels 81, wherein each of the solar-cell panel 81 has an upper edge 82, a lower edge 83, two side edges 84, an upper surface, and a lower surface, the solar-cell panels are jointed at the upper edges and the lower edges in turn, the side edges form two straight lines, in such a manner that the solar-cell group 8 is formed,
a plurality of fixing components 85, provided on joints between the solar-cell panels for fixedly connecting the two adjacent solar-panels 81, and
a plurality of water-preventers 86, fixedly provided on the joints of the upper surface of the solar-cell panels 81, for completely covering the joints and preventing rain from seeping into the joints, wherein each of the water-preventers 86 is fixedly provided on the lower edge 83 of the solar-cell panel 81, and integrated with the solar-cell panel 81;

a plurality of water channel elements 9, wherein each of the water channel elements 9 is mounted on a surface of a roof in a direction perpendicular to a ridge 91 of the roof and between the two solar-cell panel groups 8, the water channel element 9 is closely jointed with the two adjacent solar-panel groups, each of the water channel elements has a groove provided in a middle portion of the water channel element 9 in a direction along a length of the water channel, for collecting the rain flowing from the two adjacent solar-cell panel groups 8, and leading the rain to flow away from the roof, in such manner that the roof is protected from erosion of the rain to the greatest extent, and a service life of a color steel roof is extended to 20 years from 7 years; and

a plurality of supporting fixing bases 10, mounted on the roof 12, wherein each of the supporting fixing bases 10 comprises an installing part 30, for connecting with the solar-cell panel group 8, in such a manner that the solar-cell panel group 8 is mounted on the roof 12.

Preferably, a bottom of the supporting fixing base 10 adheres to the roof through structural glue. Conventional way of drilling thread connection is changed. An original structure is not damaged, in such a manner that waterproof performance of the roof is further improved.

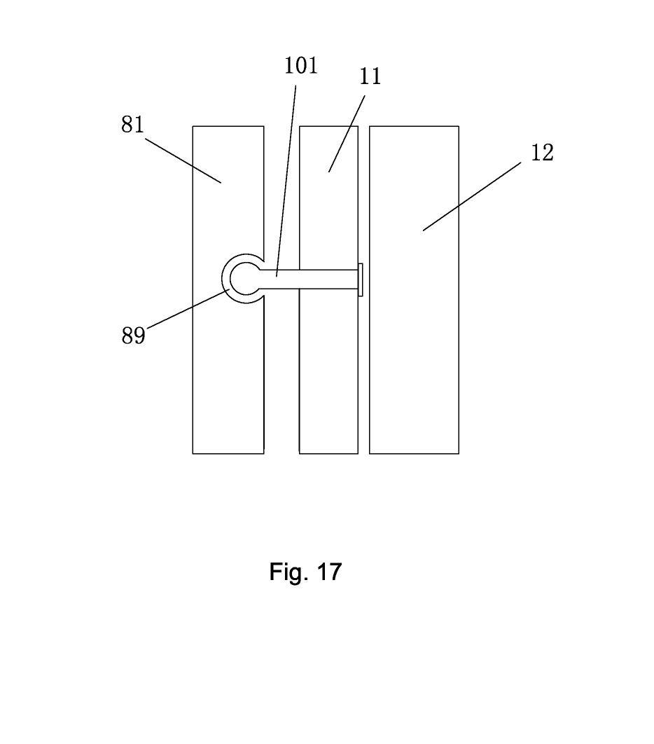

Preferably, referring to FIG. 17, the present invention provides a thorough solution to solar-cell panels of different size and different weights. For the solar-cell panels provided on a roof of a smaller span or gradient, the ridge is connected with the first solar-cell panel, the other solar-cell panels are connected in turn in a muff-coupling way. For the solar-cell panels provided on a roof of a larger span or gradient, a big quantity of solar-cell panels, a big slope, and a big sliding force are considered. Preferably, a concave caulking groove 89 is provided on each of the solar-cell panels 81, a convex column 101 is adhered to the supporting fixing base 10 in advance, and the concave caulking groove 89 is coupled with the convex column 101, in such a manner that supporting force is distributed to each of the solar-cell panels, and a supporting force provided by the ridge is reduced. The concave caulking groove 89 and the convex column 101 are combined to form a self-locking structure, and the self-locking structure is not easy to detach, in such a manner that safety of the integrated roof solar power system in the present invention is improved.

Preferably, the supporting fixing base 10 is a layer of color steel board, an asbestos board of high strength, or a plastic board 11, paved on the roof 12. The solar-cell panel is fixed by combination of the concave caulking groove 89 and the convex column 101, to ensure integrality of the roof 12, and to form the integrated roof solar power system.

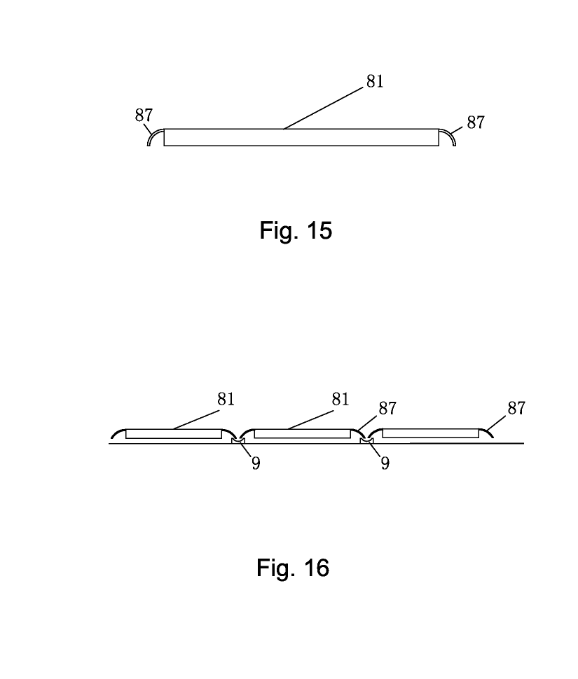

Referring to FIGS. 15-16, preferably, each of the solar-cell panels 81 further comprises two side eaves 87, fixedly provided on the two side edges 84. The side edge extends to a space above the water channel element 9, in such a manner that the rain falls into the water channel element 9 through the side eave 87, and the waterproof performance of the roof is improved.

Preferably, an upper surface of the side eave 87 has a first gradient, and the rain can flow down along the first gradient. A lower surface of the side eave 87 has a second gradient extending along the side edge 87 outwardly and downwardly, for prevent the rain from flowing to the lower surface of the solar-cell panel 81 along the lower surface of the side eave 87.

Preferably, the water channel element is in a shape of “U”, two ends of the “U” extend upwardly to connect with the side eaves 87, in such a manner that an integrated structure is formed, and the waterproof performance of the roof is further improved.

Preferably, a lower end of each of the solar-cell panel groups exceeds a lower end of the roof 12 by a certain distance, to prevent the rain from flowing down along a wall of a building, in such a manner that a structure exceeding the wall of the building is formed to discharge the rain conveniently.

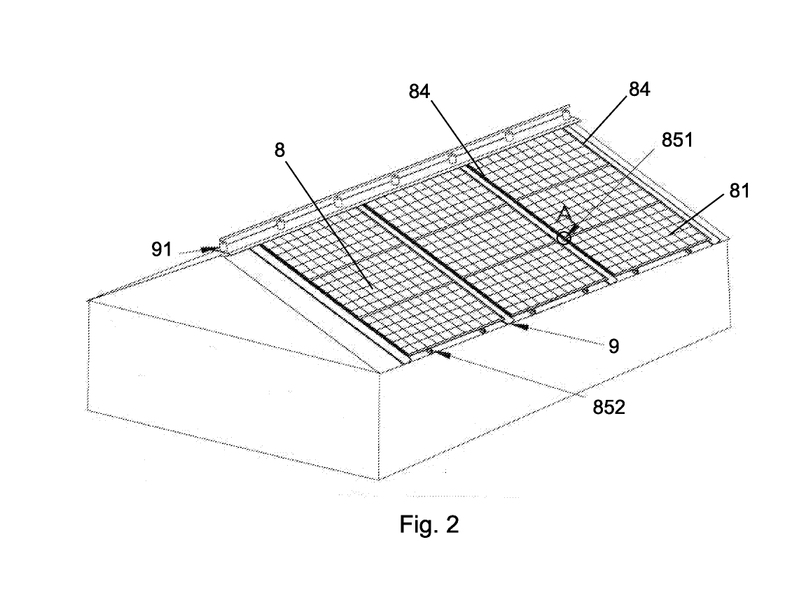

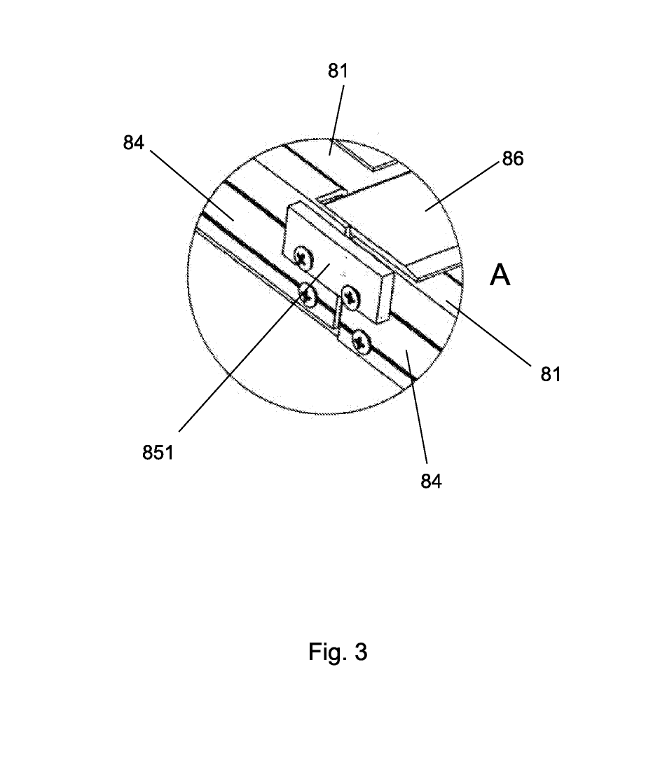

Referring to FIGS. 2-3, preferably, the fixing component 85 comprises a side edge connector 851, wherein two end portions of the side edge connector 851 are respectively connected with end portions of the side edges 84 of the two adjacent solar-cell panels 81, to fix a relative position between the two adjacent solar-cell panels 81, in such a manner that whole strength and stability of the solar-cell panel groups 8 are improved.

Referring to FIG. 1, preferably, the fixing component comprises a lower edge connecting plate 852, mounted on the lower edge 83 of the lower surface of each of the solar-cell panels, wherein the lower edge connecting plate 852 has a lower edge connecting hole, and comprises a connecting hole fixer, each of the solar-cell panels has an upper edge connecting hole, provided on the upper edge 82 of the lower surface of each of the solar-cell panels, the connecting hole fixer crosses through both of the lower edge connecting hole of a first solar-cell panel and the upper edge connecting hole of a second solar-cell panel, to fix a relative position between the first solar-cell panel and the second solar-cell panel.

Preferably, for the solar-cell panels directly mounted on beams and girders, the solar-cell panels are produced by a conventional procedure, but outer frames of the solar-cell panels can be customized according to different roofs and installing ways.

Preferably, each of the solar-cell panels has an insulating layer 88, adhered to the lower surface of the solar-cell panel by an adhesive, in such a manner that the insulating layer 88 is integrated with the solar-cell panel to further improve heat-insulating performance of the integrated roof solar power system.

Preferably, for solar-cell panel components installed on the color steel roof or cement roof, the frames of the solar-cell panel components are produced according to the above two designs. The lower portion is embedded to hide the upper portion. The fixing way is embodied as a hanging way, and the solar-cell panels are hanged on the ridge.

The solar-cell panels are preferably crystalline silicon components having a size of 1640 mm×992 mm, or amorphous silicon components having a size of 1408 mm×1108 mm. The components can be divided into two parts or four parts, and the size of the component can be adjusted flexibly to adapt different roofs.

Preferably, the solar-cell panel components are produced according to different roof structures and requirements, and the solar-cell panel components could be in a size of 1.5˜2 m², 1˜1.5 m², or 0.5˜1 m².

Preferably, according to requirements of customers, the solar-cell panel components comprising insulating materials adhered to the lower surfaces thereof are produced to strengthen heat-insulating effect of the building.

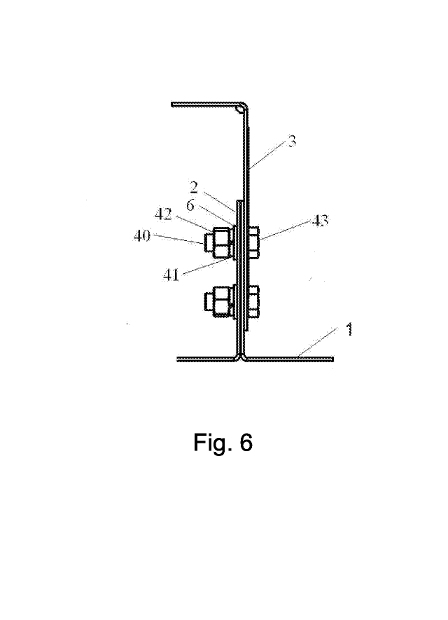

Referring to FIGS. 6˜10, preferably, the supporting fixing base comprises:

a base 1;

a first adjusting plate 2, provided on the base 1, having a first adjusting hole 21, wherein the first adjusting plate 2 has a first faying surface with the installing part 30;

a second adjusting plate 3, having a second adjusting hole 31 cooperating with the first adjusting hole 21, wherein the second adjusting hole 31 can move relative to the first adjusting hole 21 to adjust a height of the installing part 30, the first adjusting hole 21 and the second adjusting hole 31 have an overlapped portion, and a common hole 50 is defined by the overlapped portion; and

a fixer, comprising:

a main body 40, having an inserting part 41 and a fixing nut 42, the main body 40 inserts into the common hole 50 from a first side of the first adjusting plate 2 or the second adjusting plate 3, the fixing nut 42 has a faying surface with a periphery of the common hole 50, and

a pressing nut 43, provided at a second side opposite to the first side, and sleeving the inserting part 41, wherein the pressing nut 43 has a second faying surface with the first adjusting plate 2 or the second adjusting plate 3 at the periphery of the common hole 50, for pressing the first adjusting plate 2 and the second adjusting plate 3 tightly, frictions exist among the first adjusting plate 2, the second adjusting plate 3, and the fixer, with help of the frictions, the second adjusting plate 3 and the main body 40 of the fixer cooperate to fix the first adjusting plate 2 and the second adjusting plate 3.

Preferably, the first adjusting hole 21 is a closed hole defined by two opposite semicircles and a rectangular between the two semicircles. The second adjusting hole 31 has a shape and a size same as the first adjusting hole. The fixer is coupled with the first adjusting hole 21 and the second adjusting hole 31, and can slide in the first adjusting hole 21 and the second adjusting hole 31.

Preferably, the supporting fixing base further comprises gaskets 6, respectively provided between the fixing nut 42 and the first adjusting plate 2, and between the pressing nut 43 and the second adjusting plate 3. The gaskets can also be respectively provided between the fixing nut 42 and the second adjusting plate 3, and between the pressing nut 43 and the first adjusting plate 2. Thus, the frictions among the fixer, the first adjusting plate 2, and the second adjusting plate 3 are increased to achieve a better fixing effect.

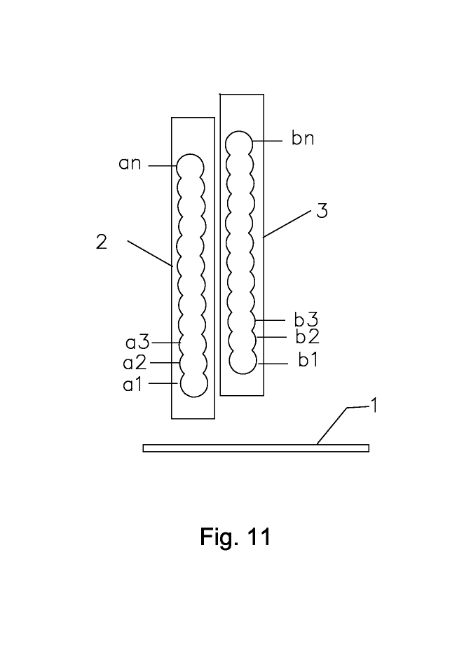

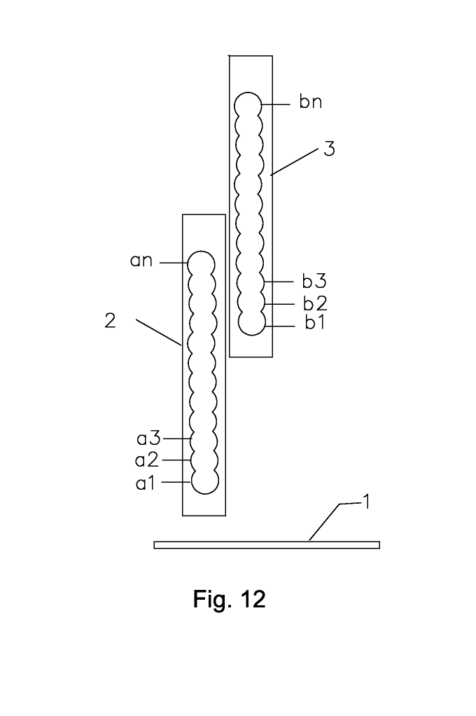

Referring to FIGS. 11˜12, preferably, the first adjusting hole is defined by n circles having equal diameters, wherein the n circles overlap in turn and are arranged in a straight line along the first adjusting plate, and the n circles are denoted as a1, a2 . . . an, from top to bottom. The second adjusting hole has a shape and a size same as the first adjusting hole, and n circles in the second adjusting hole are denoted as b1, b2 . . . bn, from top to bottom, wherein when the b1 respectively overlaps with a1, a2 . . . an, the height of the installing part can be further adjusted.

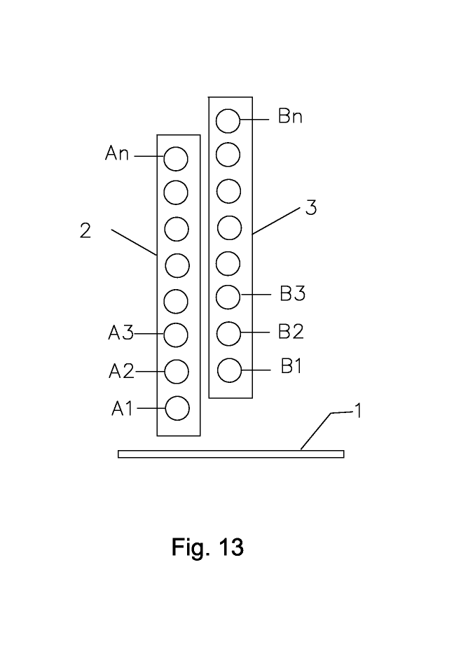

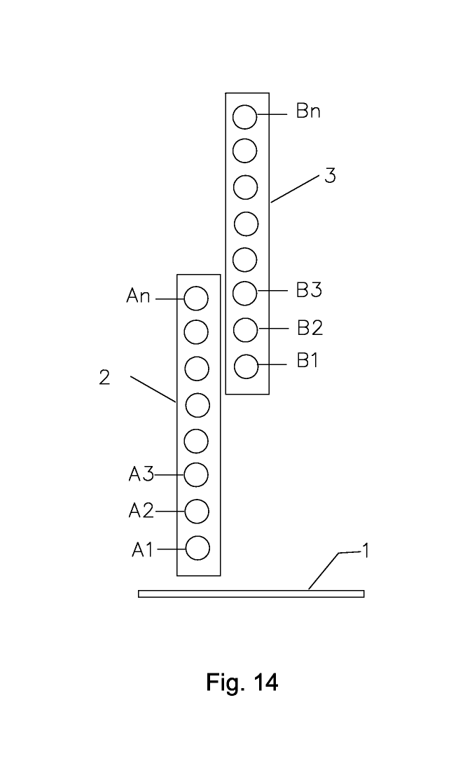

Referring to FIGS. 13˜14, preferably, the first adjusting plate has n first adjusting holes, arranged in a straight line along the first adjusting plate by a preset distance, wherein the first adjusting holes are denoted as A1, A2 . . . An. The second adjusting plate has n second adjusting holes having a size same as the first adjusting holes, and the second adjusting holes are arranged in a straight line along the second adjusting plate by the preset distance, wherein the second adjusting holes are denoted as B1, B2 . . . Bn. When the B1 respectively overlaps with A1, A2 . . . An, the height of the installing part can be further adjusted.

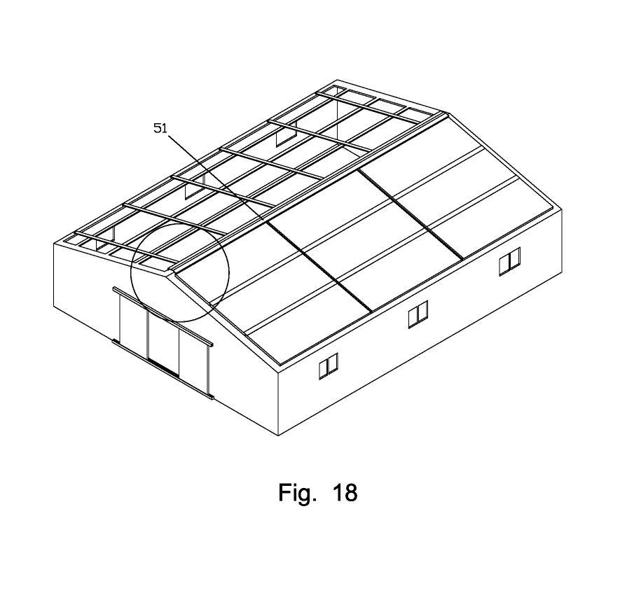

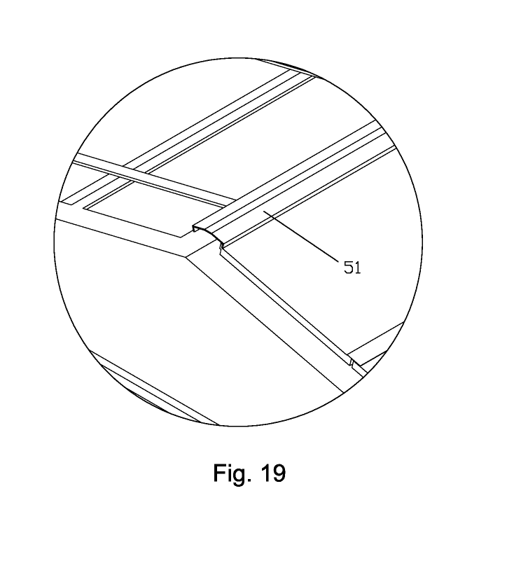

Preferably, referring to FIGS. 18˜19, the integrated roof solar power system further comprises a ridge element 51, embodied as a stainless steel cover, provided on a joint between the solar-cell panel groups 8 positioned at two sides of a ridge of the building. The ridge element 51 covers the joint to prevent the rain from infiltrating into the joint. Then the solar-cell panels 81 are installed on the roof from top to bottom.

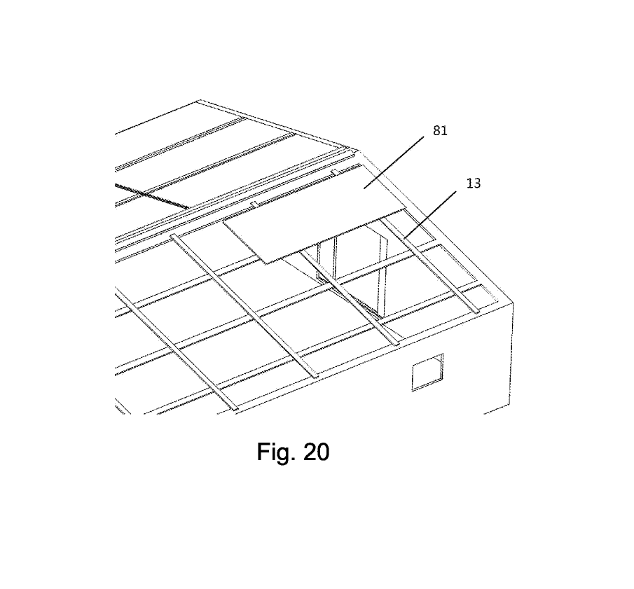

Preferably, referring to FIG. 20, for a new roof, the integrated roof solar power system further comprises an auxiliary connector 13 provided on the roof, to further support the solar-cell panels 81. Aluminium alloy frames of the solar-cell panels 81 in the present invention have various different connecting structures and standards to adapt different roofs. The present invention has a wide application prospect.

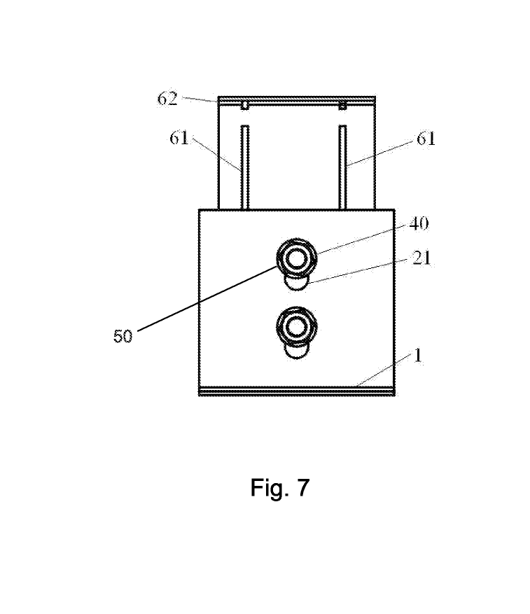

Referring to FIGS. 6-8, preferably, the first adjusting plate 2 comprises at least one reinforcer 61, provided on the first adjusting plate 2 in a vertical direction. The second adjusting plate 3 comprises at least one reinforcer 61, provided on the second adjusting plate 2 in a vertical direction. At least one reinforcer 61 are respectively provided on the base and the installing part to improve whole strength and rigidity of the supporting fixing base of the integrated roof solar power system, and prevent bending and deformation.

A method for installing an integrated roof solar power system comprises:
(1) forming a solar-cell panel group with a plurality of solar-cell panels;
(2) installing water channel elements on a roof, wherein each of the water channel elements is arranged in a direction perpendicular to a ridge, distances between the water channel elements are equal with each other, and the distance is equal to a width of the solar-cell panel group, in such a manner that the solar-cell panel groups can be closely jointed with the adjacent water channel elements;
(3) adhering supporting fixing base on the roof with structural glue; and
(4) fixing the solar-cell panel groups assembled on the roof via the supporting fixing bases, and closely jointing each of the solar-cell panel groups with the adjacent water channel elements.

Preferably, in the step (1), the solar-cell panels are connected via a plurality of fixing components provided at joints between two adjacent solar-cell panels. The fixing component comprises a lower edge connecting plate, mounted on a lower edge of a lower surface of each of the solar-cell panels, wherein the lower edge connecting plate has a lower edge connecting hole, and comprises a connecting hole fixer, each of the solar-cell panels has an upper edge connecting hole, provided on the upper edge of the lower surface of each of the solar-cell panels, and the connecting hole fixer crosses through both of the lower edge connecting hole of a first solar-cell panel and the upper edge connecting hole of a second solar-cell panel, to fix a relative position between the first solar-cell panel and the second solar-cell panel. The upper edge of the second solar-cell panel and the lower edge of the first solar-cell panel overlap, and the upper edge of the second solar-cell panel is under the lower edge of the first solar-cell panel, in such a manner that a waterproof function is realized.

### Embodiment 2

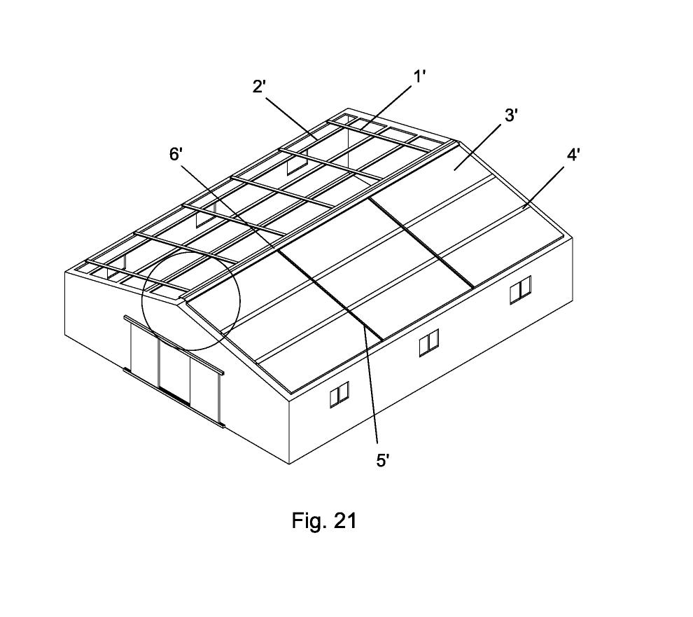

Referring to FIGS. 21˜23, an integrated roof solar power system comprises:

a plurality of supporting bar 1′, mounted on secondary ridges 2′ of a building in a direction perpendicular to the secondary ridges 2′;

a plurality of solar-cell panels 3′, mounted on the supporting bar 1′, wherein each of the solar-cell panels 3′ has an upper edge 31′, a lower edge 32′, and two side edges 33′, the solar-cell panels are jointed at the upper edges 31′ and the lower edges 32′ in turn, to form a plurality of upper and lower edge joints, the solar-cell panels are jointed at the side edges 33′, to form a plurality of side edge joints;

a plurality of lower edge water-preventers 4′, fixedly provided on the lower edge 32′ of each of the solar-cell panels 3′, for covering the upper and lower edge joints to prevent rain from infiltrating into the upper and lower edge joints;

a plurality of side edge water-preventers 5′, fixedly provided on each of the side edge joints 35′, for covering the side edge joints to prevent the rain from infiltrating into the side edge joints; and

a ridge element 6′, fixedly mounted on a ridge of the building, for covering a gap between the upper edges 31′ of the solar-cell panels adjacent to the ridge to prevent the rain from infiltrating into the gap.

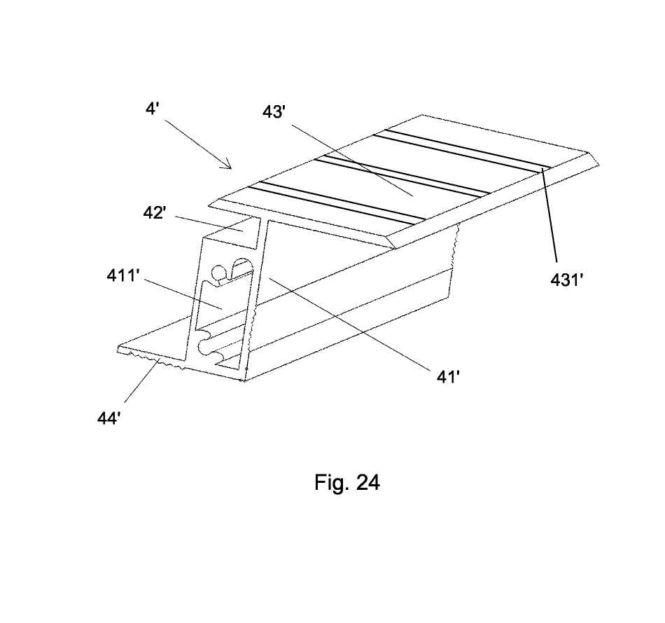

Referring to FIG. 24, preferably, the lower edge water-preventer 4′ comprises: a lower edge middle element 41′, having a lower edge groove 42′ provided horizontally on a side wall of the lower edge middle element 41′, wherein a width of the lower edge groove 42′ is equal to a thickness of the solar-cell panels 3′, in such a manner that the solar-cell panel can be exactly inserted into the lower edge groove 42′, and the solar-cell panel is fixed and supported by the lower edge groove 42′; and a lower edge water-guider 43′, fixedly connected with an upper end of the lower edge middle element 41′, for covering the upper and lower edge joint between the two adjacent solar-cell panels to prevent the rain from infiltrating into the upper and lower edge joint.

Referring to FIG. 24, preferably, each of the lower edge water-preventers 4′ further comprises: a lower edge base 44′, fixedly connected with an lower end of the lower edge middle element 41′, and a lower edge base connector, wherein the lower edge base 44′ is mounted on the supporting bar 1 ‘via the lower edge base connector, to fix the solar-cell panels 3 on the roof.

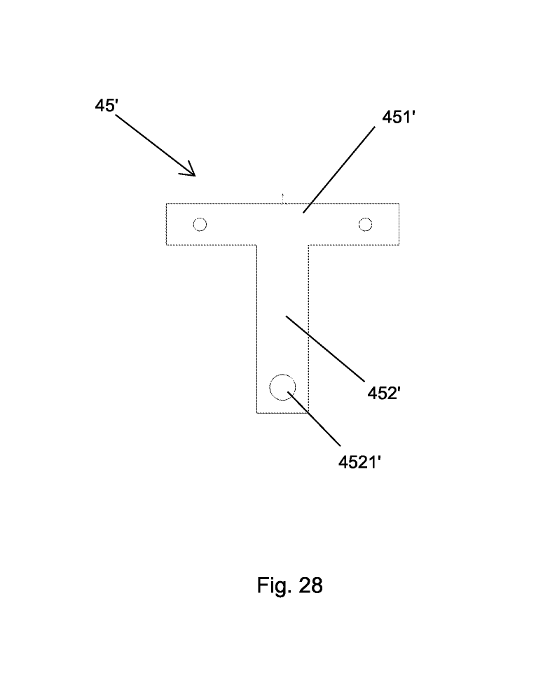

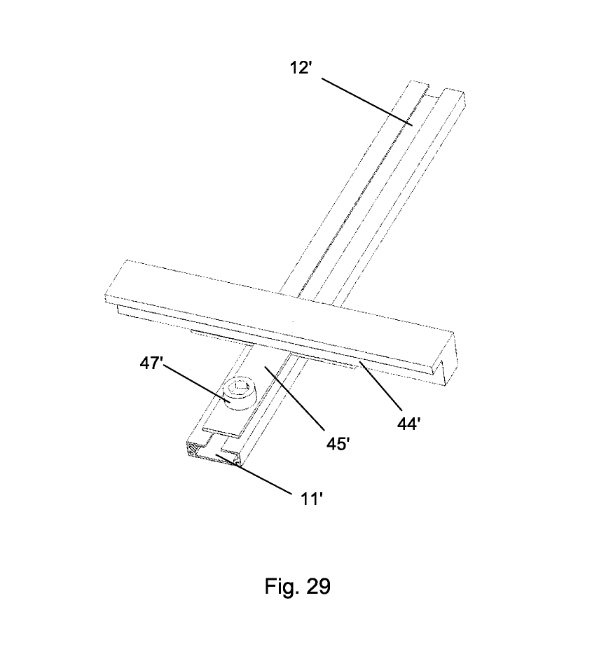

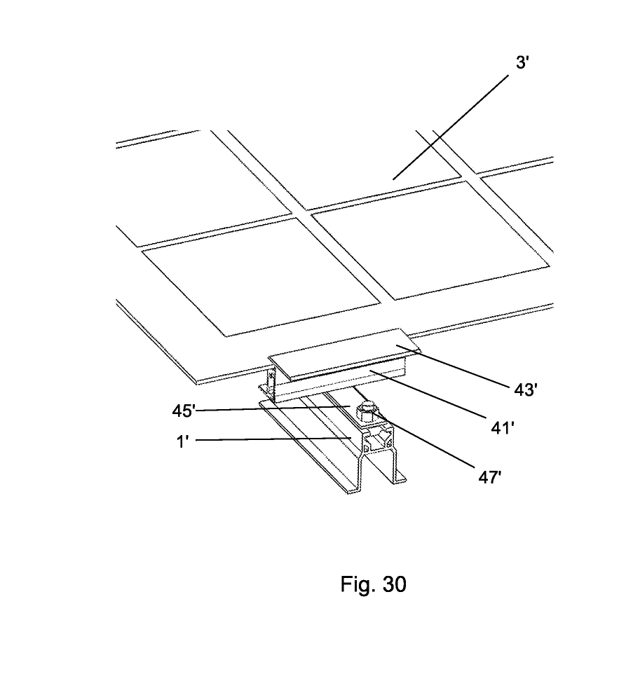

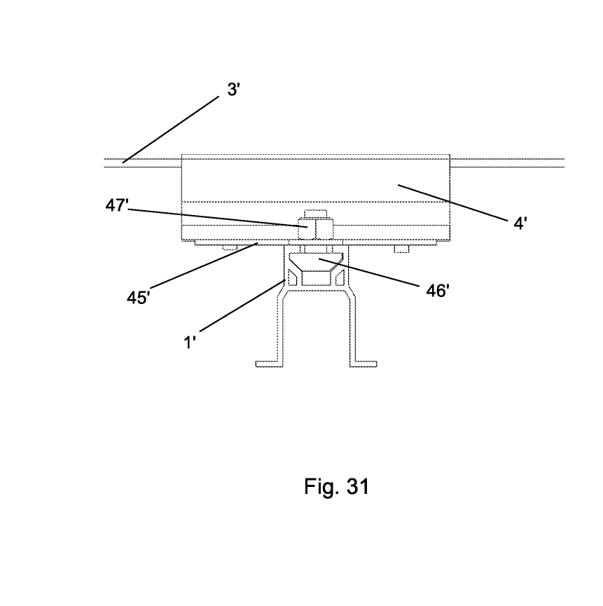

Referring to FIG. 28, preferably, the lower edge base connector comprises: a lower edge base connecting plate 45’, comprising a lower edge connecting part 451′, and a supporting bar connecting part 452′, wherein a first end of the supporting bar connecting part 452′ is fixedly connected with a middle portion of the lower edge connecting part 451′ to form a shape of “T”, the lower edge connecting part 451′ is fixedly connected with the lower edge base 44′ of the lower water-preventer 4′, the supporting bar connecting part 452′ is connected with the supporting bar 1′, in such a manner that the solar-cell panels 3′ are mounted on the supporting bars 1′.

Preferably, the lower edge connecting part 451′ and the supporting bar connecting part 452′ are integrated.

Referring to 28˜31, preferably, the supporting bar connecting part 452′ has a supporting bar connecting hole 4521′. The supporting bar 1′ has an inner chamber 11′ and a slot 12′, wherein the slot 12′ and the inner chamber 11′ are connected, the supporting bar 1′ has a hollow semi-closed structure in general, and a cross section of the supporting bar 1′ is in a shape of “C”. The lower edge base connector further comprises a fastening block 46′, provided in the inner chamber 11′, wherein the fastening block 46′ can slide in the inner chamber 11′, a size of the fastening block is larger than a width of the slot 12′, in such a manner that the fastening block can not slide out from the slot. The fastening block has a fixing hole, which has a fixing hole thread provided on an inner wall of the fixing hole, and a fastening element 47′, coupling with the fixing hole thread. The fastening element 47′ crosses through the supporting bar connecting hole 4521′ and the slot, and is connected with the fastening block via the fixing hole thread. When installing the fastening element 47′, the fastening element 47′ is tightened downwardly, until a relative position between the base connecting plate 45′ and the supporting bar 1′ is fixed. At this time, the fastening block can not slide in the inner chamber.

Referring to FIG. 24, preferably, the lower edge middle element 41′ has a lower edge chamber 411′. When the lower edge middle element 41′ is shocked or squeezed, the lower edge chamber 411′ deforms to absorb energy to realize a quake-proof function. The lower edge chamber 411′ is filled with air. Air has a good function of heat insulation, because molecules of air are relatively few and far between, and there is no close contact surface between air the lower edge middle element 41′. Thus, heat preservation performance of the solar power system on the new roof is improved.

Referring to FIG. 24, preferably, the lower edge water-guider 43′ has a plurality of lower edge gutters 431′ provided on the lower edge water-guider 43′ in a direction perpendicular to the ridge, and the lower edge gutters lead the rain to flow along the lower edge gutters 431′, in such a manner that the rain flow away from the roof layer by layer.

Preferably, the lower edge middle element 41′, the lower edge water-guider 43′ and the lower edge base 44′ are provided integrated.

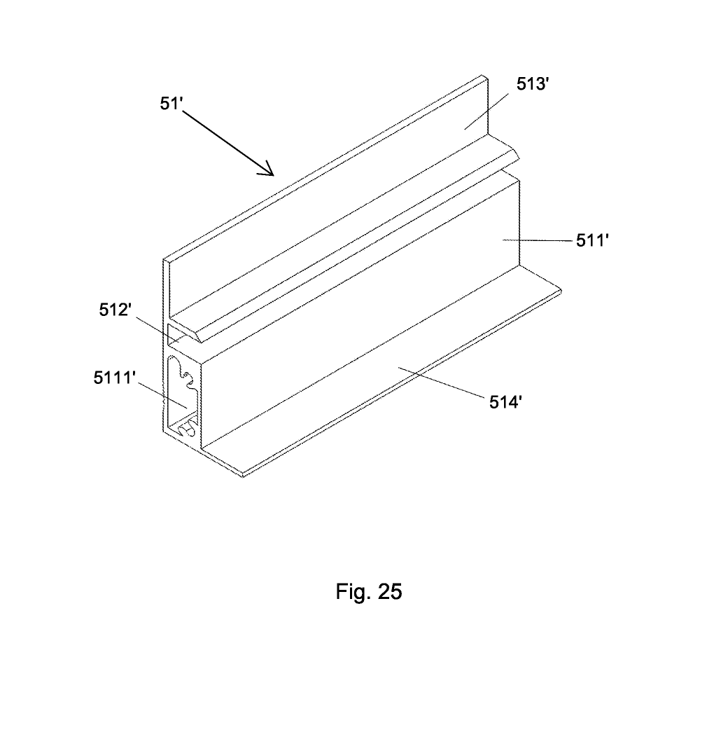

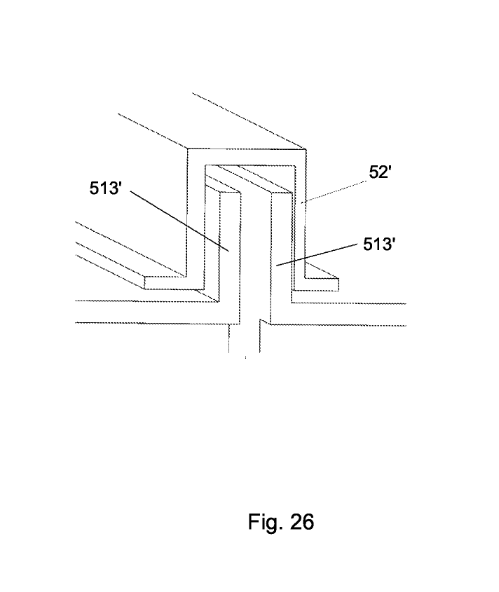

Referring to FIGS. 25˜26, preferably, the side edge water-preventer 5′ comprises:

two side edge fixers 51′, wherein each of the side edge fixers 51′ comprises:
a side edge middle element 511′, having a side edge groove 512′ provided horizontally on a side wall of the side edge middle element 511′, wherein a width of the side edge groove 512′ is equal to a thickness of the solar-cell panels 3′, in such a manner that the solar-cell panel 3′ can be exactly inserted into the side edge groove 512′, and the solar-cell panel is fixed and supported by the side edge groove 512′, and
a side edge guiding board 513′, wherein an lower end of the side edge guiding board 513′ is mounted on the side edge middle element 511′, the side edge guiding board 513′ extends upwardly along a direction of the middle element 511′, a height of extending is preferably 15 mm, the two side edge fixers 51′ respectively sleeve the side edges 33′ of the solar-cell panel 3′, the side edge guiding boards 513′ of the side edge fixers 51′ of the two adjacent solar-cell panels 3′ resist tightly; and

a side edge guiding cover 52′ in a shape of reversed “U”, sleeving upper ends of the two side edge guiding boards 513′ resisting tightly, to cover a gap between the side edge guiding boards 513′, and to prevent the rain from infiltrating into the gap between the side edge guiding boards 513′.

Referring to FIG. 25, preferably, each of the side edge fixers 51′ further comprises: a side edge base 514′, fixedly connected with the side edge middle element 511′, for fixing and supporting the side edge middle element 511′.

Referring to FIG. 25, preferably, the side edge middle element 511′ has a side edge chamber 5111′, wherein when the side edge middle element 511′ is shocked or squeezed, the side edge chamber 5111′ deforms to absorb energy to realize a quake-proof function, the side edge chamber 5111′ is filled with air, air has a good function of heat insulation, because molecules of air are relatively few and far between, and there is no close contact surface between air the side edge middle element 511′, thus, heat preservation performance of the solar power system on the new roof is improved.

Preferably, the side edge middle element and the side edge guiding board is integrated.

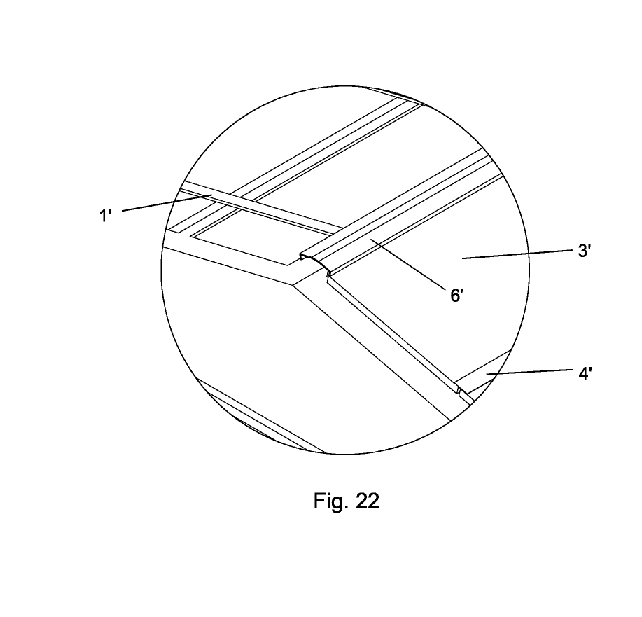

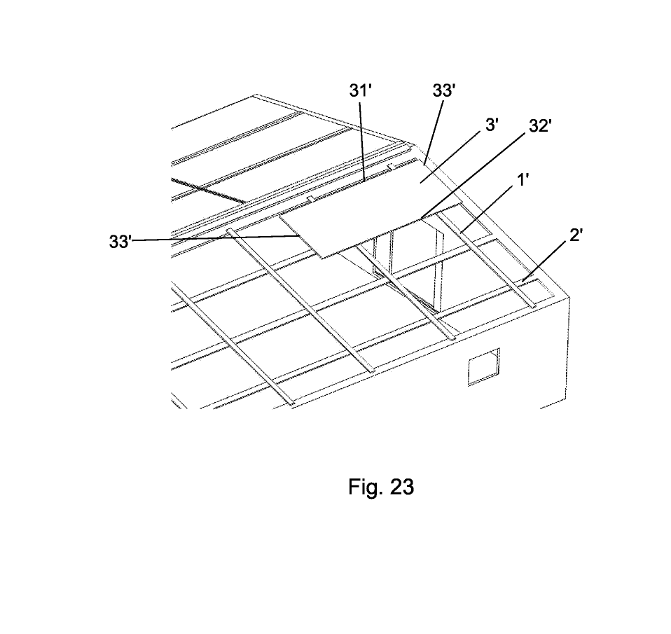

Referring to FIG. 22, preferably, each of the solar-cell panels 3′ adjacent to the ridge further comprises: an upper edge water-preventer 7′, mounted on the upper edge 31′ of the solar-cell panel 3′, extending by a distance along the upper edge 31′, wherein the distance is preferably 15 mm, the ridge element 6′ is in a shape of reversed “U”, and sleeves on the upper edge water-preventers 7′ for covering a gap between the upper edge water-preventers 7′ of the solar-cell panels adjacent to the ridge to prevent the rain from infiltrating into the gap.

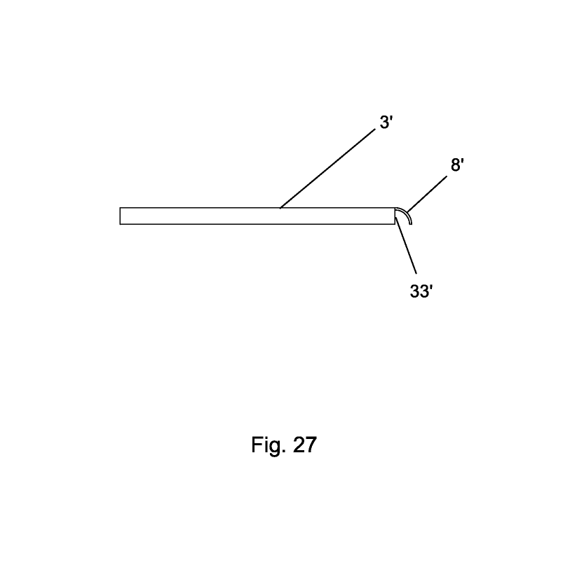

Referring to FIG. 27, preferably, each of the solar-cell panels 3′ in the side positions of the roof further comprises: a side eave 8′, mounted on the side edge close to outside of the roof, extending by a distance outwardly, wherein the side eave 8′ has a first gradient on an upper surface thereof, the rain can flow down along the first gradient, the side eave 8′ has a second gradient on an lower surface thereof, extending along the side edge 33′ outwardly and downwardly, to prevent the rain from flowing to the lower surface of the solar-cell panel 3′ along the lower surface of the side eave 8′.

Preferably, each of the solar-cell panels has an insulating layer, adhered to the lower surface of the solar-cell panel by an adhesive, in such a manner that the insulating layer is integrated with the solar-cell panel to further improve heat-insulating performance of the integrated roof solar power system.

The solar-cell panels are preferably crystalline silicon components having a size of 1640 mm×992 mm, or amorphous silicon components having a size of 1408 mm×1108 mm. The components can be divided into two parts or four parts, and the size of the component can be adjusted flexibly to adapt different roofs.

Preferably, the solar-cell panel components are produced according to different roof structures and requirements, and the solar-cell panel components could be in a size of 1.5˜2 m², 1˜1.5 m², or 0.5˜1 m².

Preferably, according to requirements of customers, the solar-cell panel components comprising insulating materials adhered to the lower surfaces thereof are produced to strengthen heat-insulating effect of the building.

A method for installing an integrated roof solar power system comprises:
(1) mounting supporting bars 1′ on secondary ridges 2′ of a building;
(2) respectively sleeving a lower edge water-preventer 4′ and side edge fixers 51′ on a lower edge and side edges of each of solar-cell panels 3′;
(3) installing the first solar-cell panel 3′ along a ridge, and mounting the first solar-cell panel 3′ on the supporting bar 1′ via a lower edge base connector;
(4) installing the second solar-cell panel against the lower edge 32′ of the first solar-cell panel, which comprises: displacing an upper edge 31′ of the second solar-cell panel under a lower edge water-guider 43′ of the lower edge water-preventer 4′ firstly, and mounting the second solar-cell panel on the supporting bar 1′ via the lower edge base connector;
(5) installing the other solar-cell panels in turn according to step (4), wherein the side edge fixers 51′ of the adjacent solar-cell panels are jointed closely, in such a manner that the solar-cell panels are paved closely on the supporting bar 1′;
(6) installing a side edge guiding cover 52′ on joints of the side edge fixers 51′; and
(7) installing a ridge element on a gap between the upper edges 31′ of the solar-cell panels adjacent to the ridge.

One skilled in the art will understand that the embodiment of the present invention as shown in the drawings and described above is exemplary only and not intended to be limiting.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. An integrated roof solar power system, comprising:
a roof unit, provided on a roof;
a plurality of solar-cell panels, mounted on said roof unit, wherein each of said solar-cell panel has an upper edge, a lower edge, and two side edges, said solar-cell panels are jointed at said upper edges and said lower edges in turn to form a plurality of upper and lower edge joints, said solar-cell panels are jointed at said side edges to form a plurality of side edge joints;
a plurality of lower edge water-preventers, mounted on said lower edges of said solar-cell panels, to cover said upper and lower edge joints and prevent rain from infiltrating into said upper and lower edge joints;
a plurality of side edge water-preventers, mounted in positions of said side edge joints, to cover said side edge joints and prevent rain from infiltrating into said side edge joints; and
a ridge element, mounted on a ridge of a building, to cover a gap between said upper edges of said solar-cell panels adjacent to said ridge and prevent rain from infiltrating into said joint.

2. The integrated roof solar power system, as recited in claim 1, wherein said lower edge water-preventer comprises:
a lower edge middle element, having a lower edge groove provided horizontally on a side wall thereof, a width of said lower edge groove is equal to a thickness of said solar-cell panels, in such a manner that said solar-cell panel can be exactly inserted into said lower edge groove and said solar-cell panel is fixed and supported by said lower edge groove; and
a lower edge water-guider, fixedly connected with an upper end of said lower edge middle element, for covering said upper and lower edge joint between said two adjacent solar-cell panels to prevent the rain from infiltrating into said upper and lower edge joint.

3. The integrated roof solar power system, as recited in claim 2, wherein each of said lower edge water-preventers further comprises: a lower edge base, fixedly connected with an lower end of said lower edge middle element, and said lower edge base is mounted on said roof unit for fixing a position of said solar-cell panel on the roof.

4. The integrated roof solar power system, as recited in claim 3, wherein said roof unit comprises a plurality of supporting bars, mounted on secondary ridges of a building in a direction perpendicular to said secondary ridges, said lower edge water-preventer further comprises a lower edge base connector, and said lower edge base is mounted on said supporting bar via said lower edge base connector to fix said position of said solar-cell panel on the roof.

5. The integrated roof solar power system, as recited in claim 4, wherein said lower edge base connector comprises:
a lower edge base connecting plate, comprising:
a lower edge connecting part, and
a supporting bar connecting part, wherein a first end of said supporting bar connecting part is fixedly connected with a middle portion of said lower edge connecting part to form a shape of “T”, said lower edge connecting part is fixedly connected with said lower edge base of said lower water-preventer, and said supporting bar connecting part is connected with said supporting bar, in such a manner that said solar-cell panels are mounted on said supporting bars.

6. The integrated roof solar power system, as recited in claim 5, wherein said supporting bar connecting part has a supporting bar connecting hole, said supporting bar has an inner chamber and a slot, said slot and said inner chamber are connected, said supporting bar has a hollow semi-closed structure in general, a cross section of said supporting bar is in a shape of “C”,
said lower edge base connector further comprises:
a fastening block, provided in said inner chamber, wherein said fastening block can slide in said inner chamber, a size of said fastening block is larger than a width of said slot, in such a manner that said fastening block cannot slide out from said slot, said fastening block has a fixing hole, which has a fixing hole thread provided on an inner wall thereof, and
a fastening element coupling with said fixing hole thread, said fastening element crosses through said supporting bar connecting hole and said slot, and is connected with said fastening block via said fixing hole thread, when installing said fastening element, said fastening element is tightened downwardly, until a relative position between said base connecting plate and said supporting bar is fixed, and at this time, said fastening block cannot slide in said inner chamber.

7. The integrated roof solar power system, as recited in claim 3, wherein said roof unit comprises a roof covering, said lower edge base is adhered to said roof covering via structural glue.

8. The integrated roof solar power system, as recited in claim 7, further comprising a plurality of supporting fixing bases, fixedly adhered to said roof covering, wherein each of said supporting fixing bases comprises an installing part, for connecting with said solar-cell panel, in such a manner that said solar-cell panel is mounted on the roof.

9. The integrated roof solar power system, as recited in claim 8, wherein said supporting fixing base comprises:
a base;
a first adjusting plate, provided on said base, having a first adjusting hole, wherein said first adjusting plate has a first faying surface with said installing part;
a second adjusting plate, having a second adjusting hole cooperating with said first adjusting hole, wherein said second adjusting hole can move relative to said first adjusting hole to adjust a height of said installing part, said first adjusting hole and said second adjusting hole have an overlapped portion, and a common hole is defined by said overlapped portion; and
a fixer, comprising:
a main body, having an inserting part and a fixing nut, said main body inserts into said common hole from a first side of said first adjusting plate or said second adjusting plate, said fixing nut has a faying surface with a periphery of said common hole, and
a pressing nut, provided at a second side opposite to said first side, and sleeving said inserting part, wherein said pressing nut has a second faying surface with said first adjusting plate or said second adjusting plate at said periphery of said common hole, for pressing said first adjusting plate and said second adjusting plate tightly, frictions exist among said first adjusting plate, said second adjusting plate, and said fixer, with help of the frictions, said second adjusting plate and said main body of said fixer cooperate to fix said first adjusting plate and said second adjusting plate.

10. The integrated roof solar power system, as recited in claim 9, wherein said first adjusting hole is a closed hole defined by two opposite semicircles and a rectangular between said two semicircles, said second adjusting hole has a shape and a size same as said first adjusting hole, and said fixer is coupled with said first adjusting hole and said second adjusting hole, and can slide in said first adjusting hole and said second adjusting hole.

11. The integrated roof solar power system, as recited in claim 9, wherein said first adjusting plate has n first adjusting holes, arranged in a straight line along said first adjusting plate by a preset distance, wherein said first adjusting holes are denoted as A1, A2 . . . An, said second adjusting plate has n second adjusting holes having a size same as said first adjusting holes, said second adjusting holes are arranged in a straight line along said second adjusting plate by said preset distance, said second adjusting holes are denoted as B1, B2 . . . Bn, and when said B1 respectively overlaps with A1, A2 . . . An, said height of said installing part can be further adjusted.

12. The integrated roof solar power system, as recited in claim 9, wherein said first adjusting hole is defined by n circles having equal diameters, said n circles overlap in turn and are arranged in a straight line along said first adjusting plate, and said n circles are denoted as a1, a2 . . . an, from top to bottom, said second adjusting hole has a shape and a size same as said first adjusting hole, n circles in said second adjusting hole are denoted as b1, b2 . . . bn, from top to bottom, and when said b1 respectively overlaps with a1, a2 . . . an, said height of said installing part can be further adjusted.

13. The integrated roof solar power system, as recited in claim 9, wherein said supporting fixing base further comprises gaskets, respectively provided between said fixing nut and said first adjusting plate, and between said pressing nut and said second adjusting plate, said gaskets can also be respectively provided between said fixing nut and said second adjusting plate, and between said pressing nut and said first adjusting plate, thus, the frictions among said fixer, said first adjusting plate, and said second adjusting plate are increased to achieve a better fixing effect.

14. The integrated roof solar power system, as recited in claim 1, wherein said lower edge middle element has a lower edge chamber, when said lower edge middle element is shocked or squeezed, said lower edge chamber deforms to absorb energy to realize a quake-proof function, said lower edge chamber is filled with air, air has a good function of heat insulation, because molecules of air are relatively few and far between, and there is no close contact surface between air said lower edge middle element, and heat preservation performance of said solar power system on the new roof is improved.

15. The integrated roof solar power system, as recited in claim 1, wherein said side edge water-preventer comprises:
two side edge fixers, wherein each of said side edge fixers comprises:
a side edge middle element, having a side edge groove provided horizontally on a side wall thereof, a width of said side edge groove is equal to a said thickness of said solar-cell panels, in such a manner that said solar-cell panel can be exactly inserted into said side edge groove and said solar-cell panel is fixed and supported by said side edge groove, and
a side edge guiding board, wherein an lower end of said side edge guiding board is mounted on said side edge middle element, said side edge guiding board extends upwardly along a direction of said middle element, said two side edge fixers respectively sleeve said side edges of said solar-cell panel, said side edge guiding boards of said side edge fixers of said two adjacent solar-cell panels resist tightly; and
a side edge guiding cover in a shape of reversed “U”, sleeving upper ends of said two side edge guiding boards resisting tightly, to cover a gap between said side edge guiding boards, and to prevent the rain from infiltrating into said gap between said side edge guiding boards.

16. The integrated roof solar power system, as recited in claim 1, wherein said side edge middle element has a side edge chamber, when said side edge middle element is shocked or squeezed, said side edge chamber deforms to absorb energy to realize a quake-proof function, said side edge chamber is filled with air, air has a good function of heat insulation, because molecules of air are relatively few and far between, and there is no close contact surface between air said side edge middle element, and heat preservation performance of said solar power system on the new roof is improved.

17. The integrated roof solar power system, as recited in claim 2, wherein said lower edge water-guider has a plurality of lower edge gutters provided on said lower edge water-guider in a direction perpendicular to said ridge, and said lower edge gutters lead the rain to flow along said lower edge gutters, in such a manner that the rain flow away from the roof layer by layer.

18. The integrated roof solar power system, as recited in claim 1, wherein each of said solar-cell panels adjacent to said ridge further comprises: an upper edge water-preventer, mounted on said upper edge of said solar-cell panel, extending by a distance along said upper edge, said ridge element is in a shape of reversed “U” and sleeves on said upper edge water-preventers for covering a gap between said upper edge water-preventers of said solar-cell panels adjacent to said ridge to prevent said rain from infiltrating into said gap.

19. The integrated roof solar power system, as recited in claim 1, wherein each of said solar-cell panels in the side positions of the roof further comprises: a side eave, mounted on said side edge close to outside of the roof, extending by a distance outwardly, said side eave has a first gradient on an upper surface thereof, the rain can flow down along said first gradient, said side eave has a second gradient on an lower surface thereof, extending along said side edge outwardly and downwardly, to prevent the rain from flowing to said lower surface of said solar-cell panel along said lower surface of said side eave.

20. A method for installing an integrated roof solar power system, as recited in claim 1, comprising:
(1) mounting supporting bars on secondary ridges of a building;
(2) respectively sleeving a lower edge water-preventer and side edge fixers on a lower edge and side edges of each of solar-cell panels;
(3) installing the first solar-cell panel along a ridge, and mounting the first solar-cell panel on the roof unit via a lower edge base connector;
(4) installing the second solar-cell panel against the lower edge of the first solar-cell panel, which comprises: displacing an upper edge of the second solar-cell panel under a lower edge water-guider of the lower edge water-preventer firstly, and mounting the second solar-cell panel on the roof unit via the lower edge base connector;
(5) installing the other solar-cell panels in turn according to step (4), wherein the side edge fixers of the adjacent solar-cell panels are jointed closely, in such a manner that the solar-cell panels are paved closely on the roof unit;
(6) installing a side edge guiding cover on joints of the side edge fixers; and
(7) installing a ridge element on a gap between the upper edges of the solar-cell panels adjacent to the ridge.
